(19) United States
(12) Patent Application Publication
(10) Pub. No.: US 2011/0095756 A1
(43) Pub. Date: Apr. 28, 2011

(54) MAGNETOCHEMICAL SENSOR

(75) Inventors: Michel Paul Barbara Van Bruggen, Helmond (NL); Mischa Megens, Eindhoven (NL); Hans Van Zon, Waalre (NL); Ralph Kurt, Eindhoven (NL); Roel Penterman, Eindhoven (NL); Emiel Peeters, Eindhoven (NL)

(73) Assignee: KONINKLIJKE PHILIPS ELECTRONICS, N.V., EINDHOVEN (NL)

(21) Appl. No.: 12/158,065

(22) PCT Filed: Nov. 24, 2006
(86) PCT No.: PCT/IB06/54415

§ 371 Date: Oct. 28, 2008

(30) Foreign Application Priority Data
Dec. 21, 2005 (EP) 05112642.3

(51) Int. Cl. G01R 33/09

(52) U.S. Cl. 324/252

(57) ABSTRACT

The application is directed to a sensor element for use in a magnetochemical sensor, which comprises a first gel-like material (10), especially a swellable hydrogel such as polyacrylamide, and a magnetic second material (20) in the form of particles, especially magnetite (Fe304) nanoparticles, embedded in the first material along with a receptor for an alalyte, eg glucose. Changes in magnetic field due to interaction with the analyte are detected with GMR element (50). Applications include biosensors, DNA testing devices, and high throughput screening.

The present invention is directed to the field of devices for the detection of one or more analytes in a sample, especially to the field of devices for the detection of biomolecules in aqueous solution.

The present invention is directed to the detection of analytes in fluids, especially to the detection of biomolecules in aqueous solution.

A magnetochemical sensor is disclosed in the U.S. Pat. No. 5,821,129 which is hereby incorporated by reference. The device layout is such that the sensor and the sensor read-out are spatially separated, enabling remote sensing. However, the sensor in the U.S. Pat. No. 5,821,129 suffers drawbacks when employing it for continuous monitoring of physiological parameters inside the body of a human. For example the sensor read-out is done by subjecting an alternating magnetic field to the stacked sensor structure and measuring a voltage from a detection unit comprising a coiled structure. This methodology hampers miniaturization of the device. Furthermore the device requires a sensor unit consisting of at least three layers, two being magnetic and one being responsive to a certain stimulus. The invention considers remote sensing which is not desirable in case of long-term implantation where one would desire to have the complete device implanted.

It is therefore an object of the present invention to provide a magnetochemical sensor which allows a quicker detection and can for most applications be miniaturized.

This object is solved by a sensor according to claim 1 of the present invention.

Accordingly, a magnetochemical sensor, especially for determining the presence, identity, amount and/or concentration of at least one analyte in a fluid sample is provided, comprising

(a) a first material, whereby the first material is an elastic material adapted to change its physical properties according to interaction with said at least one analyte; and
(b) a second material embedded in said first material whereby the second material is a magnetic material

A sensor according to the present invention shows for most applications at least one of the following advantages

a suppressed biofouling due to a high water content in said elastic material

a high biocompatibility due to a high water content in said elastic material

a fast response due to small thickness of said elastic material

a high accuracy

a small form factor

a low-cost system design

In the sense of the present invention, the term “elastic” especially means, includes and/or describes a property of a material, that can be at least partially elastic deformed, i.e. the deformation is at least partially (or completely) reversible (gets its old shape, size, dimension back). In the sense of the present invention “elastic” especially means includes and/or describes a fully reversible process of shape recovery.

In the sense of the present invention, the term “magnetic” especially means, includes and/or describes the property of a material to exhibit a net permanent magnetic dipole moment.

According to a preferred embodiment of the present invention, the second material comprises a superparamagnetic material. In the sense of the present invention, the term “superparamagnetic” especially means, includes and/or describes that this material only exhibits a net magnetic dipole moment in the presence of a magnetic field.

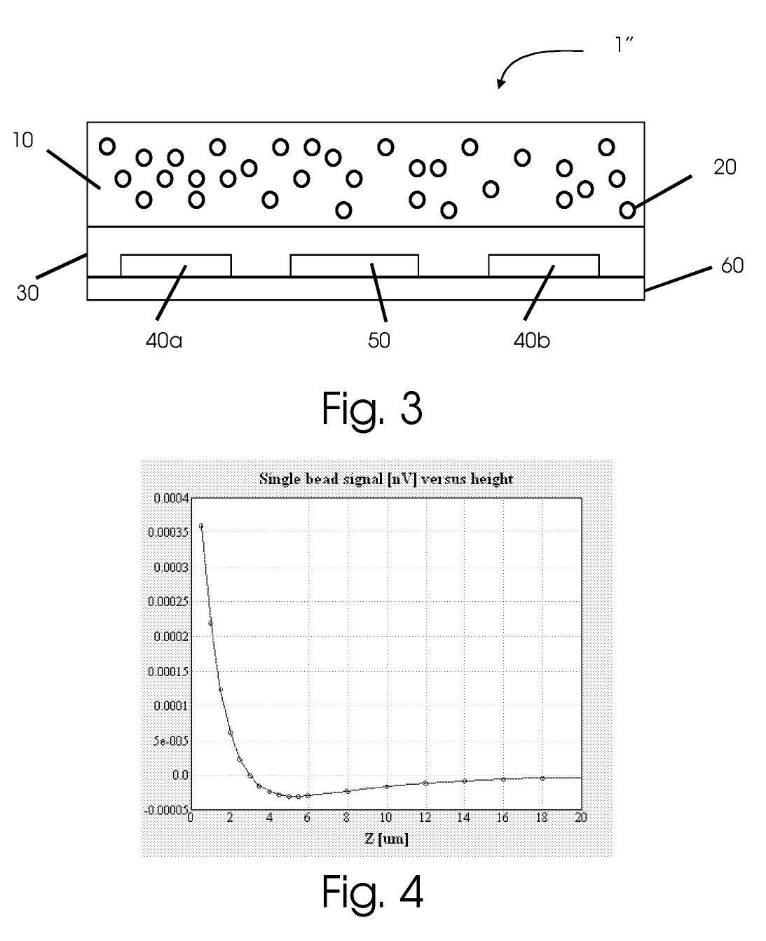

This has been shown to be advantageous for a wide range of application within the present invention, especially in case that the magnetic field is delivered by excitation wires (cf. e.g. FIG. 3). When the magnetic field is switched off, the net magnetic dipole moment of the particles becomes zero again and no field is detected by the sensor. This phenomenon allows modulation of the signal and to do a readout at a specific frequency by which means noise can be largely suppressed.

According to a preferred embodiment of the present invention, the second material comprises a permanently magnetized material.

It has been shown for a wide range of applications within the present invention that by doing so, the signal-to-noise-ratio may be improved due to the high magnetic moment of the second material. Furthermore, in a wide range of applications within the present invention, the power may be lowered and the readout electronics may be eased.

According to a preferred embodiment of the present invention, the first material changes its size and/or thickness when interacting with the at least one analyte.

According to an embodiment of the present invention, the second material is provided as small particles that are dispersed inside the first material and that are not able to diffuse or migrate out of the first material.

According to an embodiment of the present invention, the first material is provided in form of a gel.

According to a further embodiment of the present invention, there is a changing direction, essentially in which the change of the first material in response to the at least one analyte occurs. Preferably, the change of the first material includes shrinking and/or swelling.

According to a further embodiment of the present invention, the device comprises a sensor having a sensor direction and the changing direction is essentially perpendicular to the sensor direction.

The term “sensor direction” especially means and/or includes that in case the sensor extends itself in one or two dimensions larger than in the other two (or one), so that the sensor is either somewhat flat or forms a needle, the “sensor direction” would then be the direction where the sensor has its longest extension.

According to an embodiment of the present invention, the saturation magnetization of the second material is ≧0.1×10⁵ A/m and ≦2×10⁶ A/m.

According to an embodiment of the present invention, the saturation magnetization of the second material is ≧1.5×10⁵ A/m and ≦8×10⁵ A/m.

According to an embodiment of the present invention, the saturation magnetization of the second material is ≧3×10⁵ A/m and ≦6×10⁵ A/m.

According to an embodiment of the present invention, the saturation magnetization of the second material is ≧4×10⁵ A/m and ≦5.5×10⁵ A/m.

According to an embodiment of the present invention, the Langevin susceptibility (susceptibility at zero applied magnetic field) of the second material is ≧10⁻⁵ and ≦10⁵.

According to an embodiment of the present invention, the Langevin susceptibility (susceptibility at zero applied magnetic field) of the second material is ≧10⁻⁴ and ≦10⁴.

According to an embodiment of the present invention, the Langevin susceptibility (susceptibility at zero applied magnetic field) of the second material is ≧10⁻³ and ≦10³.

According to an embodiment of the present invention, the concentration (expressed as percent of the total volume) of the second material in said first material is ≧0.1% and ≦20%.

According to an embodiment of the present invention, the concentration (expressed as percent of the total volume) of the second material in said first material is ≧1% and ≦15%.

According to an embodiment of the present invention, the concentration (expressed as percent of the total volume) of the second material in said first material is ≧5% and ≦10%.

According to an embodiment of the present invention, the product of magnetization [in A/m] and concentration [in % of the total volume] of the second material is ≧10³ and ≦4*10⁷.

According to an embodiment of the present invention, the product of magnetization [in A/m] and concentration [in % of the total volume] of the second material is ≧10⁴ and ≦8*10⁶.

According to an embodiment of the present invention, the product of magnetization [in A/m] and concentration [in % of the total volume] of the second material is ≧5*10⁴ and ≦7*10⁵.

According to an embodiment of the present invention, the average particle size of the second material is ≧1 nm and ≦40 nm.

According to an embodiment of the present invention, the average particle size of the second material is ≧5 nm and 30 nm.

According to an embodiment of the present invention, the polydispersity of the second material is ≧1% and ≦40%.

According to an embodiment of the present invention, the polydispersity of the second material is ≧10% and ≦25%.

According to an embodiment of the present invention, the magnetic anisotropy constant of the second material is ≧1*10³ J/m³ and ≦1*10⁵ J/m³.

According to an embodiment of the present invention, the magnetic anisotropy constant of the second material is ≧5*10³ J/m³ and ≦5*10⁴ J/m³.

According to an embodiment of the present invention, the magnetic anisotropy constant of the second material is ≧8*10³ J/m³ and ≦1.2*10⁴ J/m³.

According to an embodiment of the present invention, the first material is provided in form of a layer.

The term “layer” means and/or includes especially that the thickness of the first material in one dimension is ≧0% and ≦50% than in either one of the other dimensions.

For some applications within the present invention, the layer thickness is bound to a range in order to obtain optimum device properties: On the one hand to thin a layer will yield a low signal and insufficient sensitivity whereas to thick a layer will yield a slow response due to long diffusion times.

According to an embodiment of the present invention, the first material is provided in form of a layer with a thickness of ≧0.5 μm and ≦40 μm.

According to an embodiment of the present invention, the first material is provided in form of a layer with a thickness of ≧5 μm and ≦30 μm.

According to an embodiment of the present invention, the first material is provided in form of a layer with a thickness of ≧10 μm and ≦20 μm.

According to an embodiment of the present invention, the first material comprises a hydrogelic material.

In the sense of the present invention, the term “hydrogelic material” means and/or includes especially that this material comprises polymers that in water form a water-swollen network.

The term “hydrogel material” in the sense of the present invention furthermore especially means that at least a part of the hydrogel material comprises polymers that form in water a water-swollen network and/or a network of polymer chains that are water-soluble. Preferably, the hydrogel material in swollen state comprises ≧50% water and/or solvent, more preferably ≧70% and most preferred ≧90%, whereby preferred solvents include organic solvents, preferably organic polar solvents and most preferred alkanols such as Ethanol, Methanol and/or (Iso-) Propanol.

In the sense of the present invention, the term “hydrogelic material” means and/or includes especially that the hydrogel is responsive which means that it displays a change of shape and total volume upon a change of a specific parameter. Such parameter can be a physical (temperature, pressure) or chemical property (ionic concentration, pH, analyte concentration) or biochemical property (enzymatic activity).

According to an embodiment of the present invention, the hydrogel material comprises a material selected out of the group comprising poly(meth)acrylic materials, silicagel materials, substituted vinyl materials or mixture thereof.

According to an embodiment of the present invention, the hydrogel material comprises a substituted vinyl material, preferably vinylcaprolactam and/or substituted vinylcaprolactam.

According to an embodiment of the present invention, the hydrogel material comprises a poly(meth)acrylic material made out of the polymerization of at least one (meth)acrylic monomer and at least one polyfunctional (meth)acrylic monomer.

According to an embodiment of the present invention, the (meth)acrylic monomer is chosen out of the group comprising (meth)acrylamide, acrylic esters, hydroxyethyl(meth)acrylate, ethoxyethoxyethyl(meth)acrylate or mixtures thereof.

According to an embodiment of the present invention, the polyfunctional (meth)acrylic monomer is a bis-(meth)acryl and/or a tri-(meth)acryl and/or a tetra-(meth)acryl and/or a penta-(meth)acryl monomer.

According to an embodiment of the present invention, the polyfunctional (meth)acrylic monomer is chosen out of the group comprising bis(meth)acrylamide, tetraethylene glycol di(meth)acrylate, triethylene glycol di(meth)acrylate, diethylene glycol di(meth)acrylate, tripropyleneglycol di(meth)acrylates, pentaerythritol tri(meth)acrylate polyethyleneglycol di(meth)acrylate, ethoxylated bisphenol-A-di(meth)acrylate, hexanedioldi(meth)acrylate or mixtures thereof.

According to an embodiment of the present invention, the hydrogel material comprises an anionic poly(meth)acrylic material, preferably selected out of the group comprising (meth)acrylic acids, arylsulfonic acids, especially styrenesulfonic acid, itaconic acid, crotonic acid, sulfonamides or mixtures thereof, and/or a cationic poly(meth)acrylic material, preferably selected out of the group comprising vinyl pyridine, vinyl imidazole, aminoethyl (meth)acrylates or mixtures thereof, co-polymerized with at least one monomer selected out of the group neutral monomers, preferably selected out of the group vinyl acetate, hydroxyethyl (meth)acrylate (meth)acrylamide, ethoxyethoxyethyl(meth)acrylate or mixture thereof, or mixtures thereof. These co-polymers change their shape as a function of pH and can respond to an applied electrical field and/or current by as well. Therefore, these materials may be of use for a wide range of applications within the present invention.

According to an embodiment of the present invention, the first material comprises a hydrogelic material comprising thermo-sensitive polymers.

According to an embodiment of the present invention, the first material comprises a hydrogelic material comprising monomers selected out of the group comprising poly-N-isopropylamide (PNIPAAm) and copolymers thereof with monomers selected out of the group comprising polyoxyethylene, trimethylol-propane distearate, poly-ε-caprolactone or mixtures thereof.

According to an embodiment of the present invention, the hydrogel material is based on thermo-responsive monomers selected out of the group comprising N-isopropylamide, diethylacrylamide, carboxylsopropylacrylamide, hydroxymethylpropylmethacrylamide, acryloylalkylpiperazine and copolymers thereof with monomers selected out of the group of hydrophilic monomers, comprising hydroxyethyl(meth)acrylate, (meth)acrylic acid, acrylamide, polyethyleneglycol(meth)acrylate or mixtures thereof, and/or co-polymerized with monomers selected out of the group hydrophobic monomers, comprising (iso)butyl(meth)acrylate, methylmethacrylate, isobornyl(meth)acrylate or mixtures thereof. These co-polymers are known to be thermo-responsive and therefore may be of use for a wide range of applications within the present invention.

According to an embodiment of the present invention, the first material comprises a hydrogelic material with a swelling ratio (with the second material embedded in the first material) of ≧1% and ≦500% at 20° C.

In the sense of the present invention, the swelling ratio especially includes, means or refers to a measurement according to the following procedure:

The first and second material was dried to form a film in an oven under the temperature of 50° C. The film was immersed in an excess of deionized water to remove the residual unreacted compounds. The swollen polymer film was then cut into disk forms with 8 mm in diameter and dried at 50° C. until the weight no longer changed. A preweighed dried sample (W₀) was immersed in an excess of deionized water in a thermostatic water bath until the swelling equilibrium was attained. The weight of the wet sample (W₁) was determined after the removal of the surface water via blotting with filter paper. The equilibrium swelling ration was calculated with the following formula

swelling ratio=(W₁−W₀)/W₀

According to an embodiment of the present invention, the first material comprises a hydrogelic material with a swelling ratio (with the second material embedded in the first material) of ≧3% and ≦200% at 20° C.

According to an embodiment of the present invention, the first material comprises a hydrogelic material with a swelling ratio (with the second material embedded in the first material) of ≧5% and ≦100% at 20° C.

According to an embodiment of the present invention, the first material comprises a hydrogelic material with a swelling ratio (with the second material embedded in the first material) of ≧1% and ≦30% at 20° C.

According to an embodiment of the present invention, the first material comprises a hydrogelic material with a swelling ratio (with the second material embedded in the first material) of ≧1% and ≦25% at 20° C.

According to an embodiment of the present invention, the first material comprises a hydrogelic material with a swelling ratio (with the second material embedded in the first material) of ≧1% and ≦20% at 20° C.

According to an embodiment of the present invention, the first material comprises a receptor for the analyte to be detected.

In the sense of the present invention, the term “receptor” means and/or includes especially that some chemical moieties are present in the first material which are capable to interact with a selected analyte e.g. by hydrostatic interactions, hydrogen bonding, chemical reception, molecular recognition and the like.

An example of such a receptor system is “calmodulin” which binds to both calcium as well as to a range of anti-spychotic molecules, referred to as the phenothiazines, [J. D. Ehrick (Nature Materials p. 298-302, Vol. 4, April 2005)], which is hereby fully incorporated by reference.

According to an embodiment of the present invention, the first material is a polymeric material.

According to an embodiment of the present invention, the first material is a polymeric material with a conversion of ≧50% and ≦100% (with the second material embedded in the first material).

In the sense of the present invention, the conversion especially includes, means or refers to a measurement according to the following procedure:

After the polymerization of the first material and the embedding of the second material, a quantitative amount of inhibitor was introduced into a sample of the first material and the sample was quickly quenched in an ice bath. For the removal of remaining monomers and initiators, the sample as washed with deionized water several times. After that, the sample was dried in vacuum oven at 70° C. until there was no change in weight anymore. The conversion was calculated as follows:

conversion=(P−F)/M₀*100%

where P is the weight of the dry copolymer composite network obtained from the sample, F is the theoretical weight of the second material incorporated in the first material and Mₒ is the weight of the monomers in the feed.

According to an embodiment of the present invention, the first material is a polymeric material with a conversion of ≧70% and ≦95% (with the second material embedded in the first material).

The term “essentially” means and/or includes especially a wt-% content of ≧90%, according to an embodiment ≧95%, according to an embodiment ≧99%.

According to an embodiment of the present invention, the crosslink density in the first material is ≧0.002 and ≦1, preferably ≧0.05 and ≦1.

In the sense of the present invention, the term “crosslink density” means or includes especially the following definition: The crosslink density δ_{X} is here defined as

$${δ}_{X} = \frac{X}{L + X}$$

where X is the mole fraction of polyfunctional monomers and L the mole fraction of linear chain (=non polyfunctional) forming monomers. In a linear polymer δ_{X}=0, in a fully crosslinked system δₓ=1.

According to an embodiment of the present invention, the second material comprises a coating.

According to an embodiment of the present invention, the second material comprises a coating which is adapted to increase the ability of the second material to attach to the hydrogel network so that the particles are fixed to the network and cannot diffuse out the network.

According to an embodiment of the present invention, the second material comprises a coating with a thickness of ≧1 nm and ≦10 nm, according to an embodiment ≧1 and ≦5 nm.

According to an embodiment of the present invention, the second material comprises a coating which consists essentially out of a material selected out of the group of inorganic oxides, polymeric organic materials, non-polymeric organic materials and mixtures thereof.

According to an embodiment of the present invention the second material and/or the core of the second material is made essentially out of a material selected out of the group comprising iron alloys, iron oxides, nickel alloys, nickel oxides, cobalt oxides, cobalt alloys, rare earth oxides, rare earth alloys rand mixtures thereof that exhibit magnetic properties.

According to an embodiment of the present invention the second material and/or the core of the second material is made essentially out of Fe₃O₄.

According to an embodiment of the present invention, the sensor comprises at least one current delivering means adapted to provide a current in such a way as to cause a change in orientation in the magnetic dipoles in the second material.

According to an embodiment of the present invention, the sensor comprises at least one measuring means which is capable of measuring the change of the physical properties of the first material according to interaction with said at least one analyte, especially using the change of position of the second material within the first material upon a change of the physical properties of the first material.

Preferably, the measuring means is selected from the group comprising electromagnetic detectors, AMR, TMR, GMR, Hall sensors, acoustic and/or optical detectors.

According to an embodiment of the present invention, the distance between the measuring means and the first material is ≧100 nm and ≦1 μm, preferably ≧200 nm and ≦500 nm.

According to an embodiment of the present invention, the distance between the measuring means and the first material is ≧100 nm and ≦1 μm, preferably ≧200 nm and ≦500 nm and the thickness of the layer of the first material is ≧1 μm and ≦5 μm, preferably ≧2 μm and ≦3 μm.

However, according to a different embodiment, the distance between the measuring means and the first material is ≧1 μm and ≦5 μm, preferably ≧2 μm and ≦3 μm.

According to an embodiment of the present invention, the distance between the measuring means and the first material is ≧1 μm and ≦5 μm, preferably ≧2 μm and ≦3 μm and the thickness of the layer of the first material is ≧10 μm and ≦25 μm, preferably ≧15 μm and ≦20 μm.

Surprisingly, the inventors have found out that for a wide range of applications within the present invention—especially if a GMR element is used as a measuring means—there may be two preferred regions for the distance between the measuring means and the first material as well as the thickness of the layer of the first material itself.

Without being bound to any theory, the inventors believe that these two regions may occur due to a turning point in single bead signal (in nV) vs. the distance from the GMR-Element, as will be explained by the two examples II and III later on.

However, it should be stressed that although this turning point has been found in a wide range of applications within the present invention, this behaviour does not necessarily needed to be found in all applications.

According to an embodiment of the present invention, the sensor comprises at least one measuring means and at least one GMR element adapted to measure the change of the resistance of an GMR element caused by the in-plane component of the magnetic stray-field of the oriented dipoles in the second material.

A GMR element suitable for use in the present invention is e.g. disclosed in the EP1459084 and cited documents within this application, which are hereby fully enclosed by reference.

According to a further embodiment of the present invention, the first material is at least partly surrounded by a well coated with a non-sticking material, which has a surface tension of ≦30 mN/m, preferably ≦25 mN/m.

According to a further embodiment of the present invention the first material is surrounded by the non-sticking material which has a surface tension of ≦30 mN/m, preferably ≦25 mN/m in substantially all directions which are perpendicular to the changing direction.

According to a further embodiment of the present invention, the non-sticking material is a fluor-containing material, preferably a fluorinated monolayer material, which was preferably made using plasma treatment, e.g. CF₄ plasma treatment or by vapour deposition of a fluorsilane e.g. perfluoroalkylchlorosilane.

According to a further embodiment, the device comprises a substrate and/or matrix material in the vicinity of the first material, whereby the device comprises at least one adhesion promoting layer between the first material and the substrate and/or matrix material.

According to a preferred embodiment of the present invention, the adhesion promoting layer is a monolayer.

Preferably the at least one adhesion promoting layer is chosen from the group silane-containing layers, thiol-containing layers, amine-containing layers or mixtures thereof.

The term “silane-containing layer” especially means and/or includes a layer which comprises a material of the form

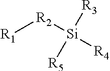

whereby R₁ is selected out of the group comprising acrylate, methacrylate, acrylamide, methacrylamide, allyl, vinyl, acetyl, amine, epoxy or thiol;

R₂ is selected out of the group alkylene, arylene, mono- or polyalkoxy, mono- or polyalkylamine, mono- or polyamide, thioether, mono- or polydisulfides,

R₃ and R₄ are independently selected out of the group halogen, R₆-R₇ (whereby R₆ is selected out of the group comprising acrylate, methacrylate, acrylamide, methacrylamide, allyl, vinyl, acetyl, amine, epoxy or thiol and R₇ is selected out of the group alkyl, aryl, mono- or polyalkoxy, mono- or polyalkylamine, mono- or polyamide, thioether, mono- or polydisulfides), O—R₈ (whereby R₈ is selected out of the group hydrogen, alkyl, long-chain alkyl, aryl, heteroaryl, halogen).

R₅ represents the group O—R₉, where R₉ is selected out of the group hydrogen, alkyl, long-chain alkyl, aryl, halogen and/or R₅ is a hydrolyzable moiety.

Generic group definition: Throughout the description and claims generic groups have been used, for example alkyl, alkoxy, aryl. Unless otherwise specified the following are preferred groups that may be applied to generic groups found within compounds disclosed herein:

alkyl: linear and branched C1-C8-alkyl,

alkylene: selected from the group consisting of:

methylene; 1,1-ethylene; 1,2-ethylene; 1,1-propylidene; 1,2-propylene; 1,3-propylene; 2,2-propylidene; butan-2-ol -1,4-diyl; propan-2-ol-1,3-diyl; 1,4-butylene; cyclohexane-1,1-diyl; cyclohexan-1,2-diyl; cyclohexan-1,3-diyl; cyclohexan-1,4-diyl; cyclopentane-1,1-diyl; cyclopentan-1,2-diyl; and cyclopentan-1,3-diyl,

long-chain alkyl: linear and branched C5-C20 alkyl

alkenyl: C2-C6-alkenyl,

cycloalkyl: C3-C8-cycloalkyl,

alkoxy: C1-C6-alkoxy,

long-chain alkoxy: linear and branched C5-C20 alkoxy

aryl: selected from homoaromatic compounds having a molecular weight under 300,

arylene: selected from the group consisting of: 1,2-phenylene; 1,3-phenylene; 1,4-phenylene; 1,2-naphtalenylene; 1,3-naphtalenylene; 1,4-naphtalenylene; 2,3-naphtalenylene; 1-hydroxy-2,3-phenylene; 1-hydroxy-2,4-phenylene; 1-hydroxy-2,5-phenylene; and 1-hydroxy-2,6-phenylene, heteroaryl: selected from the group consisting of: pyridinyl; pyrimidinyl; pyrazinyl; triazolyl; pyridazinyl; 1,3,5-triazinyl; quinolinyl; isoquinolinyl; quinoxalinyl; imidazolyl; pyrazolyl; benzimidazolyl; thiazolyl; oxazolidinyl; pyrrolyl; carbazolyl; indolyl; and isoindolyl, wherein the heteroaryl may be connected to the compound via any atom in the ring of the selected heteroaryl,

amine: the group —N(R)2 wherein each R is independently selected from: hydrogen; C1-C6-alkyl; C1-C6-alkyl-C6H5; and phenyl, wherein when both R are C1-C6-alkyl both R together may form an —NC3 to an —NC5 heterocyclic ring with any remaining alkyl chain forming an alkyl substituent to the heterocyclic ring,

halogen: selected from the group consisting of: F; Cl; Br and I,

polyether: chosen from the group comprising —(O—CH₂—CH(R))ₙ—OH and —(O—CH₂—CH(R))ₙ—H whereby R is independently selected from: hydrogen, alkyl, aryl, halogen and n is from 1 to 250.

Unless otherwise specified the following are more preferred group restrictions that may be applied to groups found within compounds disclosed herein:

alkyl: linear and branched C1-C6-alkyl,

long-chain alkyl: linear and branched C5-C10 alkyl, preferably linear C6-C8 alkyl

alkenyl: C3-C6-alkenyl,

cycloalkyl: C6-C8-cyclo alkyl,

alkoxy: C1-C4-alkoxy,

long-chain alkoxy: linear and branched C5-C10 alkoxy, preferably linear C6-C8 alkoxy

aryl: selected from group consisting of: phenyl; biphenyl; naphthalenyl; anthracenyl; and phenanthrenyl,

heteroaryl: selected from the group consisting of:

pyridinyl; pyrimidinyl; quinolinyl; pyrazolyl; triazolyl; isoquinolinyl; imidazolyl; and oxazolidinyl, wherein the heteroaryl may be connected to the compound via any atom in the ring of the selected heteroaryl, heteroarylene: selected from the group consisting of: pyridin 2,3-diyl; pyridin-2,4-diyl; pyridin-2,6-diyl; pyridin-3,5-diyl; quinolin-2,3-diyl; quinolin-2,4-diyl; isoquinolin-1,3-diyl; isoquinolin-1,4-diyl; pyrazol-3,5-diyl; and imidazole-2,4-diyl,

amine: the group —N(R)₂, wherein each R is independently selected from: hydrogen; C1-C6-alkyl; and benzyl,

halogen: selected from the group consisting of: F and Cl,

polyether: chosen from the group comprising —(O—CH₂—CH(R))ₙ—OH and —(O—CH₂—CH(R))ₙ—H whereby R is independently selected from: hydrogen, methyl, halogen and n is from 5 to 50, preferably 10 to 25.

It has been shown for a wide range of applications that this silane-containing layer helps to link the first material to the substrate and/or matrix material essentially without influencing the performance of the sensor device.

The term “thiol-containing layer” especially means and/or includes a layer which comprises a material of the form R—SH with R chosen out of the group alkyl, long-chain alkyl, alkenyl, cycloalkyl.

It has been shown for a wide range of applications that this thiol-containing layer helps to link the first material to the substrate and/or matrix material essentially without influencing the performance of the sensor device. If a thiol-containing layer is used, the surface of the matrix material is chosen out of a thiol-binding material, especially the surface of the matrix material is an Au-surface.

The term “amine-containing layer” especially means and/or includes a layer which comprises a material of the form R₁—NH—R₂ with R₁ chosen out of the group alkyl, long-chain alkyl, alkenyl, cycloalkyl, polyether and R₂ chosen out of the group hydrogen, alkyl, long-chain alkyl, alkenyl, cycloalkyl, polyether.

It has been shown for a wide range of applications that this amine-containing layer helps to link the first material to the substrate and/or matrix material essentially without influencing the performance of the sensor device. If a amine-containing layer is used, the surface of the matrix material is preferably equipped with amine-binding groups, preferably epoxy groups and/or reactive esters, halogenides and/or amines.

The present invention furthermore relates to a method of measuring the presence, identity, amount and/or concentration of at least one analyte in a sample using a sensor as described above, comprising the steps of

a) Allowing the first material to interact with the at least one analyte to cause a change of the physical properties in the first material
b) Applying a current in such a way as to cause a change in orientation in the magnetic dipoles in the second material
c) Measuring the change of the resistance of an GMR element caused by the in-plane component of the magnetic stray-field of the oriented dipoles in the second material.

A sensor and/or a method according to the present invention may be of use in a broad variety of systems and/or applications, amongst them one or more of the following:

biosensors used for molecular diagnostics

rapid and sensitive detection of proteins and nucleic acids in complex biological mixtures and body fluids such as e.g. blood, urine or saliva

high throughput screening devices for chemistry, pharmaceuticals or molecular biology

testing devices e.g. for DNA or proteins e.g. in criminology, for on-site testing (in a hospital), for diagnostics in centralized laboratories or in scientific research

tools for DNA or protein diagnostics for cardiology, infectious disease and oncology, food, and environmental diagnostics

tools for combinatorial chemistry

analysis devices

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

Additional details, features, characteristics and advantages of the object of the invention are disclosed in the subclaims, the figures and the following description of the respective figure and examples, which—in an exemplary fashion—show a preferred embodiments of a sensor according to the invention.

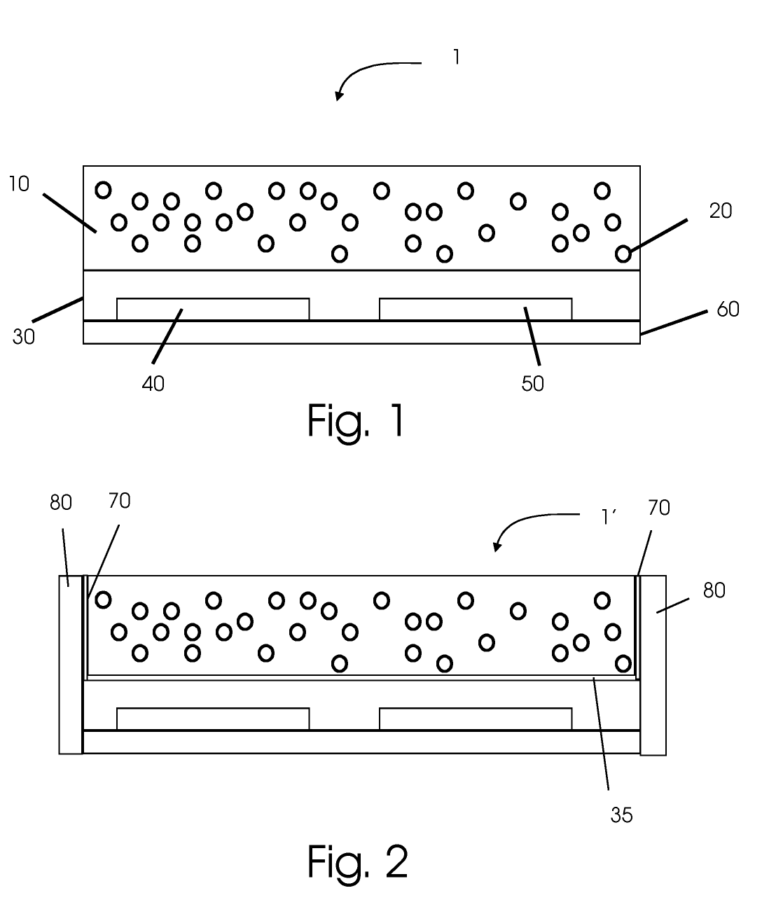

FIG. 1 shows a very schematic cross-sectional view of a sensor according to a first embodiment of the present invention;

FIG. 2 shows a schematic cross-sectional view of a sensor according to a second embodiment of the present invention;

FIG. 3 shows a schematic cross-sectional view of a sensor according to a third embodiment of the present invention;

FIG. 4 shows a diagram of the single bead signal (in nV) vs. the distance from the GMR-Element to the bead (in μm) for an embodiment according to Example II of the present invention; and

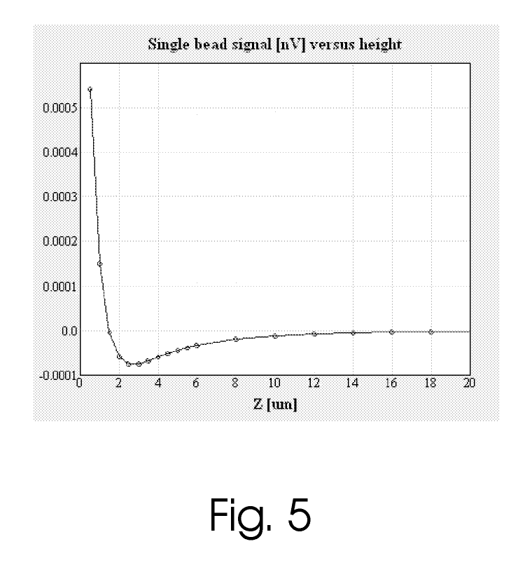

FIG. 5 shows a diagram of the single bead signal (in nV) vs. the distance from the GMR-Element to the bead (in μm) for an embodiment according to Example III of the present invention.

FIG. 1 shows a very schematic cross-sectional view of a sensor 1 according to a first embodiment of the present invention. The sensor comprises a first material 10 with embedded particles 20 of the second material therein that are employed in such way that they cannot migrate inside the first material. The particles 20 are in this embodiment in random order, however, according to a further embodiment of the present invention (not shown in the figs.) a structured pattern of the particles 20 is provided.

The first material is provided on a matrix material 30, which serves to protect a current wire 40 and a GMR sensor 50. The matrix material 30 itself is placed on a substrate 60.

According to an embodiment of the present invention, the distance between the GMR sensor 50 and the first material 10 is ≧100 nm and ≦1 μm, preferably ≧200 nm and ≦500 nm.

The matrix or at least the part of the matrix with projects towards the first material is preferably made out of SiO₂ in order to provide for a good attachment of the first material. The substrate material can be any suitable material, preferably silicon.

FIG. 2 shows a very schematic cross-sectional view of a sensor 1′ according to a first embodiment of the present invention.

In FIG. 2, the components, which are (essentially) identical with the embodiment of FIG. 1 are not discussed to avoid repetitions.

The embodiment of FIG. 2 differs from that of FIG. 1 that a silane-containing layer 35 is provided between the substrate and the first material. It should be noted that in FIG. 2 the dimensions of the silane-containing layer 35 are grossly exaggerated for visibility purposes; in most actual applications of the present invention, the silane-containing layer 35 will be a monolayer.

Furthermore, the embodiment of FIG. 2 comprises a non-sticking material 70 which is provided in the directions which are not the changing direction (which in this embodiment is vertical). Here, too the dimensions of the non-sticking material 70 are greatly enlarged for visibility purposes. The non-sticking material essentially ensures a homogenous swelling and/or shrinking of the first material.

As can be seen from FIG. 2 (in conjunction with FIG. 1), the sensor direction is essentially perpendicular (i.e. in this embodiment is the horizontal direction) to the changing direction.

The non-sticking material is itself provided with sidewalls 80, which may be of any suitable material. In some applications, resist materials, such as SU-8 have shown to be advantageous and form therefore a preferred embodiment of the present invention.

FIG. 3 shows a very schematic cross-sectional view of a sensor 1″ according to a third embodiment of the present invention. In FIG. 3, the components, which are (essentially) identical with the embodiment of FIG. 1 and/or FIG. 2 are not discussed to avoid repetitions.

FIG. 3 differs from the embodiment of FIG. 1 in that two current wires 40a, 40 b are present in between one GMR element 50.

It should be noted that the dimensions and sizes in FIG. 3 are highly schematic and may be different in actual applications within the present invention.

Actually, according to one preferred embodiment of the present invention, the width of the GMR element and/or of the current wires are ≧2 μm and ≦10 μm and according to a further embodiment of the present invention, the spacing between the GMR element and the current wire(s) is ≧0.5 μm and ≦2 μm.

Furthermore it will be apparent that a silane-containing layer and a non sticking material (as in FIG. 2) may be present in (or added to) this embodiment as well.

### EXAMPLES

The invention is furthermore—in a merely illustrated way—more to be understood by the following examples.

### Example I

In this example, a sensor according to FIG. 1 is used.

The first material is a polyacrylamide hydrogel provided with a receptor for glucose the second material consisted out of Fe₃O₄ particles with an average diameter of 15 nm. The vol-% of the second material is 10%, the initial thickness of the first material is 15 μm.

The concentration of glucose is measured the following way. A current is led through the current wire (whereby the direction of the current is perpendicular to the paper plane). This causes a change in the orientation of the magnetic dipoles of the second material, which can be detected via the GMR-sensor. The resulting voltage drop over the GMR element is dependent on the reaction of the first material with the glucose in that a decrease of the glucose concentration leads to an expansion of the first material which will cause an increase of the electrical resistance of the GMR element. When a constant current is applied to the element, this will lead to an increase of the voltage drop over the element.

In the example, the rise in voltage is in the range of tens of microVolts per 1% of volume change.

### Example II

In this example, a sensor according to FIG. 3 is used.

The distance between the GMR sensor 50 and the first material 10 is 0.5 μm. The thickness of the wires 40a, 40b is 250 nm and of GMR sensor 50 the thickness is 49 nm.

The width of the GMR sensor is 6 μm, the widths of the wires 7 μm and the spacing 1 μm.

FIG. 4 shows a diagram of the single bead signal (in nV) vs. the distance from the GMR-Element to the bead for an embodiment according to Example II. It can be clearly seen that there is a turning point somewhat around 5 μm and that the curve passes the 0V somewhat around 3 μm.

Therefore it is for this embodiment advantageous to have a maximum height of the layer 10 of about 5-6 μm.

### Example III

In this example, a sensor according to FIG. 3 was used, too.

The distance between the GMR sensor 50 and the first material 10 is 3 μm. The thickness of the wires 40a, 40 b is 250 nm and of GMR sensor 50 the thickness is 49 nm.

The width of the GMR sensor is 3 μm, the widths of the wires 3 μm and the spacing is 1 μm.

FIG. 5 shows a diagram of the single bead signal (in nV) vs. the distance from the GMR-Element to the bead for an embodiment according to Example III. It can be clearly seen that there is a turning point somewhat around 3 μm and that the curve passes the 0V somewhat around 2.5 μm.

However, since the distance between the GMR sensor 50 and the first material 10 was chosen to be 3 μm (i.e. already “over” the turning point), for this embodiment it is advantageous to have a maximum height of the layer 10 of about 15-20 μm.

The difference between the examples II and III is that in Example II the “falling branch” is measured whereas in Example III the “rising branch” is used. However, any skilled person in the art will easily see that both examples give rise to reasonable data. The actual setup of a sensor will be decided upon the desired parameter of the actual application.

The inventors have furthermore found out that for many applications within the present invention especially the width of the GMR element as well as the wire(s) may influence the “turning point”.

In case that the distance between the measuring means and the first material is ≧1 μm and ≦5 μm, preferably ≧2 μm and ≦3 μm, it is especially preferred that the width of the GMR element and/or the wire(s) is ≧1 μm and ≦5 μm, preferably ≧2 μm and ≦3 μm.

In case that the distance between the measuring means and the first material is ≧100 nm and ≦1 μm, preferably ≧200 nm and ≦500 nm it is especially preferred that the width of the GMR element and/or the wire(s) is ≧3 μm and ≦10 μm, preferably ≧5 μm and ≦8 μm.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. The invention's scope is defined in the following claims and the equivalents thereto. Furthermore, reference signs used in the description and claims do not limit the scope of the invention as claimed.

1. A magnetochemical sensor, especially for determining the presence, identity, amount and/or concentration of at least one analyte in a fluid sample comprising
(a) a first elastic material having physical properties which are changeable according to interaction with said at least one analyte; and
(b) a second magnetic material embedded in said second magnetic material.

2. The sensor according to claim 1, wherein the sensor comprises at least one current delivering means adapted to provide a current in such a way as to cause a change in orientation in magnetic dipoles in the second magnetic material and/or the sensor comprises at least one measuring means adapted to measure a change of resistance of a GMR element caused by an in-plane component of a magnetic stray-field of oriented dipoles in the second magnetic material.

3. The sensor according to claim 1, whereby the saturation magnetization of the magnetic material is ≧1×10⁵ A/m and ≦1×10⁶ A/m.

4. The sensor according to claim 1, whereby the concentration of the second magnetic material in said first elastic material is ≧1% and ≦20%.

5. The sensor according to claim 1, whereby the product of the magnetization and the concentration of the second magnetic material is ≧10³ and ≦4*10⁷.

6. The sensor according to claim 1 whereby the average particle size of the second magnetic material is ≧1 nm and ≦40 nm.

7. The sensor according to claim 1 whereby the magnetic anisotropy constant of the second magnetic material is ≧1*10³ J/m³ and ≦1*10⁵ J/m³.

8. A method of measuring the presence, identity, amount and/or concentration of at least one analyte in a sample using a sensor comprising a first elastic material and a second magnetic material embedded in said first elastic material, said method comprising the steps of
(a) Allowing the first elastic material to interact with the at least one analyte to cause a change in its physical properties
(b) Applying a current to cause a change in orientation in magnetic dipoles in the second magnetic material
(c) Measuring a change of the resistance of a GMR element caused by an in-plane component of the magnetic stray-field of oriented dipoles in the second magnetic material.

9. The method of claim 8, wherein the first elastic material changes in size and/or thickness when interacting with the at least one analyte.

10. The sensor according to claim 1, wherein the sensor is incorporated in the group consisting of
biosensors used for molecular diagnostics
rapid and sensitive detection of proteins and nucleic acids in complex biological mixtures such as e.g. blood or saliva
high throughput screening devices for chemistry, pharmaceuticals or molecular biology
testing devices e.g. for DNA or proteins e.g. in criminology, for on-site testing (in a hospital), for diagnostics in centralized laboratories or in scientific research
tools for DNA or protein diagnostics for cardiology, infectious disease and oncology, food, and environmental diagnostics
tools for combinatorial chemistry
analysis devices.
